(19) United States
(12) Patent Application Publication
(10) Pub. No.: US 2023/0126754 A1
(43) Pub. Date: Apr. 27, 2023

(54) CONTAINER AND AUTOMOBILE

(71) Applicant: Nicoldsystem Co., Ltd., Toyama (JP)

(72) Inventor: Noriyuki Ishimura, Toyama (JP)

(21) Appl. No.: 17/908,098

(22) PCT Filed: Feb. 9, 2021
(86) PCT No.: PCT/JP2021/004690

§ 371 Date: Aug. 30, 2022

(30) Foreign Application Priority Data
May 1, 2020 (JP) 2020-081358

(51) Int. Cl. F25B 21/02; B60P 3/20

(52) U.S. Cl. CPC F25B 21/02; B60P 3/20; F25B 2321/023

(57) ABSTRACT

A cool box includes: a first temperature holding chamberthat stores a first object to be cooled, a first cold insulator temperature, and a first indoor electricity generator that generates electricity on the basis of a difference between the temperatures of the first object to be cooledand the first cold insulator and holds the temperature of the first object to be cooled; a second temperature holding chamberthat stores a second object to be cooled, a second cold insulator temperature, and a second indoor electricity generatorthat generates electricity on the basis of a difference between the temperatures of the second object to be cooledand the second cold insulator and holds the temperature of the second object to be cooled; and an intra-chamber electricity generatorthat generates electricity on the basis of a difference between the temperatures of the first temperature holding chamberand the second temperature holding chamber .

### TECHNICAL FIELD

The present disclosure relates to a container and an automobile.

### BACKGROUND ART

Perishable foods such as meat, fish, and vegetables are loaded in containers of which the temperatures are controlled, and are transported between physical distribution bases by trains, automobiles, and the like.

Freezing or refrigeration apparatuses are connected to the containers in order to maintain the freshness of the perishable foods in the containers during the transportation. Commonly, the freezing or refrigeration apparatuses generate cool air using electrical energy, and maintain the perishable foods in the containers at low temperature.

However, the electrical energy may be unobtainable depending on the types of the trains, the automobiles, and the like, by which the containers are transported, and on transportation environments. Cool containers that perform isolation from outside air to prevent inflow of heat have been used as containers that can maintain the temperatures of the interiors of the container at low temperature even in such situations.

For example, an apparatus described in Patent Literature 1 is known as such a cool container.

A cold insulator cooled in advance is placed in the container, whereby the apparatus described in Patent Literature 1 maintains a perishable food, which is being transported, at low temperature even in a situation in which it is impossible to obtain electrical energy.

### CITATION LIST

### Patent Literature

Pat. Literature 1: Unexamined Japanese Pat. Application Publication No. 2015-017796.

### SUMMARY OF INVENTION

### Technical Problem

In the cool container described in Pat. Literature 1, thermal energy transfers from the perishable food to the cold insulator.

In the cool container described in Pat. Literature 1, much of the thermal energy stored in the perishable food is consumed by an increase in the temperature of the cold insulator.

As described above, the cool container described in Pat. Literature 1 has had a problem that it is impossible to efficiently utilize thermal energy transferring from an object to be cooled to the cold insulator.

In view of the problem described above, an objective of the present disclosure is to provide a container and an automobile, in which thermal energy transferring from an object to be cooled to a cold insulator can be efficiently utilized.

### Solution to Problem

In order to achieve the objective described above, a container according to one aspect of the present disclosure includes:
a first temperature holding chamber that stores a first object to be cooled, a first cold insulator of which a state is changed at a first temperature, and a first indoor electricity generator that generates electricity based on a difference between temperatures of the first object to be cooled and the first cold insulator having the first temperature, and holds the temperature of the first object to be cooled;
a second temperature holding chamber that stores a second object to be cooled, a second cold insulator of which a state is changed at a second temperature, and a second indoor electricity generator that generates electricity based on a difference between temperatures of the second object to be cooled and the second cold insulator having the second temperature, and holds the temperature of the second object to be cooled; and
an intra-chamber electricity generator that is placed between the first temperature holding chamber and the second temperature holding chamber, thermally connects the first temperature holding chamber and the second temperature holding chamber to each other, and generates electricity based on a difference between temperatures of the first temperature holding chamber and the second temperature holding chamber.

An automobile according to another aspect of the present disclosure includes:
the container;
a solar battery that supplies generated energy to the first indoor electricity generator, the second indoor electricity generator, or the intra-chamber electricity generator; and
a drive mechanism that allows a vehicle body to travels using electrical energy generated by the first indoor electricity generator, the second indoor electricity generator, or the intra-chamber electricity generator.

### ADVANTAGEOUS EFFECTS OF INVENTION

In accordance with the present disclosure, there are provided a container and an automobile, in which electricity can be generated based on a difference between the temperatures of a cold insulator and an object to be cooled, and on a difference between the temperatures of temperature holding chambers, and therefore, thermal energy transferring from the object to be cooled to the cold insulator and thermal energy transferring between the temperature holding chambers can be efficiently utilized.

### BRIEF DESCRIPTION OF DRAWINGS

FIG. 1A is a perspective view of a cool box according to Embodiment 1 of the present disclosure;

FIG. 1B is a cross sectional view taken along the line AA‘ of the cool box illustrated in FIG. 1A;

FIG. 1C is an enlarged view of an adjacent portion between one temperature holding chamber and another temperature holding chamber of the cool box illustrated in FIG. 1B;

FIG. 2A is a view illustrating a positional relationship between an electricity generation panel and electricity generation cells included in the cool box illustrated in FIG. 1A;

FIG. 2B is a perspective view of each of the electricity generation cells illustrated in FIG. 2A;

FIG. 2C is a cross sectional view taken along the line BB‘ of the electricity generation cell illustrated in FIG. 2B;

FIG. 2D is a cross sectional view taken along the line CC' of the electricity generation cell illustrated in FIG. 2B;

FIG. 3A is a view giving an explanation of a change in the state of a cold insulator of the cool box illustrated in FIG. 1A;

FIG. 3B is a view in which changes in the temperatures of the cold insulator in the case of using the cold insulator and a refrigerant in the case of using the refrigerant except the cold insulator are compared;

FIG. 4 is a view giving an explanation of energy flow in the cool box illustrated in FIG. 1A;

FIG. 5A is a perspective view of a refrigerator vehicle according to Embodiment 2 of the present disclosure;

FIG. 5B is a side view of the refrigerator vehicle illustrated in FIG. 5A;

FIG. 6 is a view giving an explanation of energy flow in the refrigerator vehicle illustrated in FIG. 5A; and

FIG. 7 is a perspective view of an electricity generation cell according to Alternative Example.

### DESCRIPTION OF EMBODIMENTS

### Embodiment 1

A cool box 1 according to Embodiment 1 of the present disclosure will be described below with reference to the drawings.

### General Description of Cool Box 1

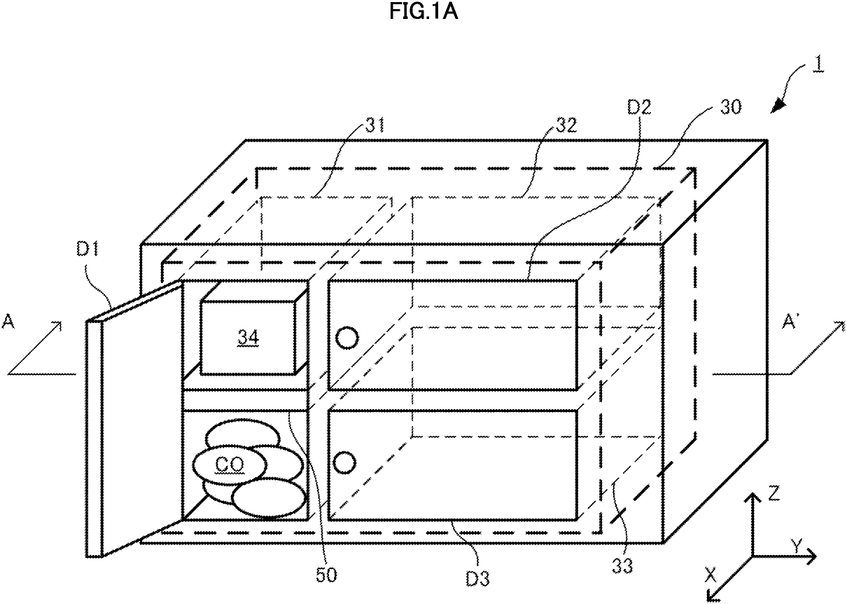

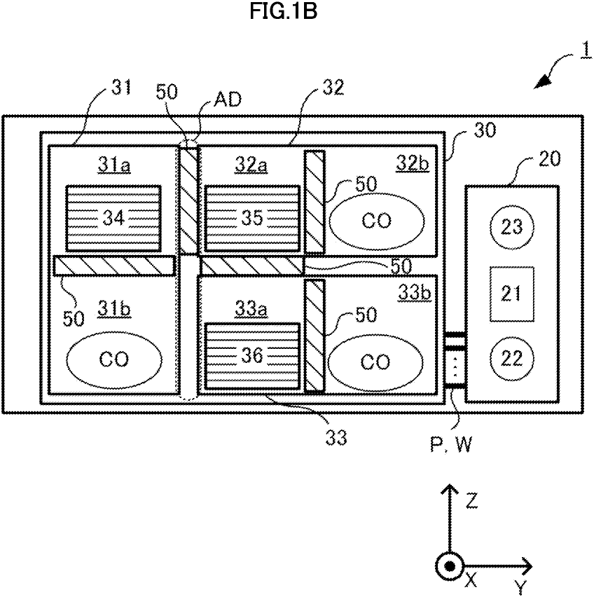

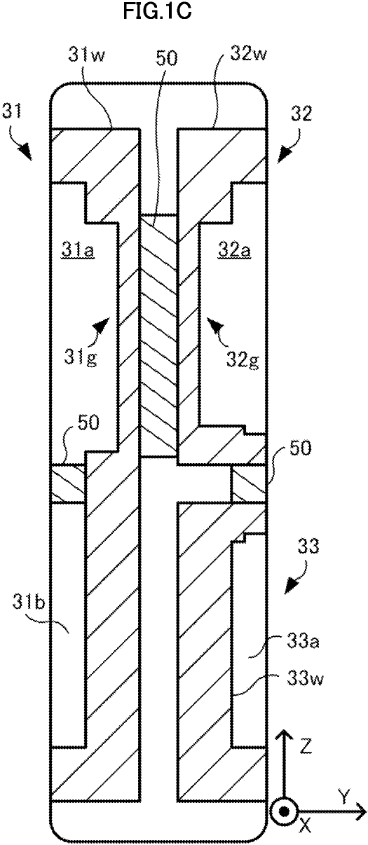

As illustrated in FIG. 1A, the cool box 1 is a box-shaped apparatus including three temperature holding chambers 31, 32, and 33 which are spaces, in which an object to be cooled CO, such as a meat, a fish, or a vegetable, are stored, and the temperature of the object is held.

More specifically, the cool box 1 includes a controller 20 that controls each portion, and a cool container 30 including the temperature holding chambers 31, 32, and 33, as illustrated in a cross sectional view that is illustrated in FIG. 1B and taken along the line AA’ of FIG. 1A.

As illustrated in FIG. 1A, the temperature holding chambers 31, 32, and 33 include doors D1, D2, and D3, respectively. When putting or taking the object to be cooled CO in or out of the temperature holding chambers 31, 32, or 33, a user opens the corresponding door D1, D2, or D3.

As specifically described later, the spaces in the temperature holding chambers 31, 32, and 33 are partitioned by electricity generation panels 50, and a cold insulator 34, 35, or 36, and the object to be cooled CO are stored in each of the partitioned spaces. The cold insulators 34, 35, and 36 have been cooled in advance.

As illustrated in FIG. 1B, the controller 20 and the cool container 30 are connected to each other through a pipes P which is pipes through which electricity generation fluid described below passes, and wiring lines W which are conductive wires through which electricity passes.

The controller 20 includes a storage battery 21, a pump 22, and an electric connector 23.

The storage battery 21 is an apparatus that stores electrical energy generated by the electricity generation panels 50.

The pump 22 is an apparatus that pressurizes the electricity generation fluid in the pipes P using the electrical energy, and circulates the electricity generation fluid to the electricity generation panels 50. The electrical energy that operates the pump 22 is supplied through the wiring lines W.

The electric connector 23 is a connector to which the power cable of an external instrument that utilizes the electrical energy is connected. The external instrument consumes the electrical energy, stored in the storage battery 21, through the electric connector 23.

### Details of Temperature Holding Chambers 31, 32, and 33

As illustrated in FIG. 1B, the space in the temperature holding chamber 31 is divided in the up-and-down direction by the electricity generation panel 50. The cold insulator 34 is stored in the upper section 31a of the temperature holding chamber 31, and the object to be cooled CO is stored in the lower section 31b of the temperature holding chamber 31.

The spaces in the temperature holding chambers 32 and 33 are divided in the right-and-left direction by the electricity generation panels 50. The cold insulator 35 is stored in the left section 32a of the temperature holding chamber 32, and the object to be cooled CO is stored in the right section 32b of the temperature holding chamber 32. Likewise, the cold insulator 36 is stored in the left section 33a of the temperature holding chamber 33, and the object to be cooled CO is stored in the right section 33b of the temperature holding chamber 33.

Both surfaces of each of the electricity generation panels 50 are held at different temperatures because the cold insulators 34, 35, and 36 are placed in the sections 31a, 32a, and 33a partitioned by the electricity generation panels 50, respectively, and the objects to be cooled CO are placed in the opposite sections 31b, 32b, and 33b.

The objects to be cooled CO are examples of a first object to be cooled and a second object to be cooled in claims.

The electricity generation panels 50 are placed not only in the temperature holding chambers 31, 32, and 33 but also between the temperature holding chambers 31, 32, and 33. Specifically, the electricity generation panels 50 are placed between the upper end of the temperature holding chamber 31 and the left end of the temperature holding chamber 32, and between the left end of the temperature holding chamber 32 and the left end of the temperature holding chamber 33, respectively.

The temperatures of both the surfaces of each of the electricity generation panels 50 placed between the temperature holding chambers 31, 32, and 33 are different because the temperatures of the temperature holding chambers 31, 32, and 33 are different, as described later.

### Fig. 1C is a View of the Enlarged AD Portion of Fig. 1B

The temperature holding chambers 31 and 32 are surrounded by thermally insulated walls 31w and 32w, respectively. The temperature holding chamber 31 and the temperature holding chamber 32 come into contact with each other via the thermally insulated wall 31w closer to the temperature holding chamber 31, the thermally insulated wall 32w closer to the temperature holding chamber 32, and the electricity generation panel 50. The temperature holding chamber 31 and the temperature holding chamber 32 are thermally insulated from each other by the thermally insulated walls 31w and 32w. However, the thermally insulated walls 31w and 32w are formed so that the heat transfer portions 31g and 32g, on which the electricity generation panel 50 is placed, of the thermally insulated walls 31w and 32w are thinner than the other portions.

Such a structure causes the temperature holding chamber 31 and the temperature holding chamber 32 to be thermally connected to each other via the heat transfer portions 31g and 32g, that is, to be able to exchange thermal energy through the heat transfer portions 31g and 32g, and the electricity generation panel 50. The temperature holding chamber 33 is surrounded by a thermally insulated wall 33w. A similar structure is provided between the temperature holding chamber 32 and the temperature holding chamber 33, and therefore, the temperature holding chamber 32 and the temperature holding chamber 33 are also thermally linked to each other.

The temperature holding chambers 31, 32, and 33 are examples of a first temperature holding chamber and a second temperature holding chamber in claims.

### Details of Electricity Generation Panel 50

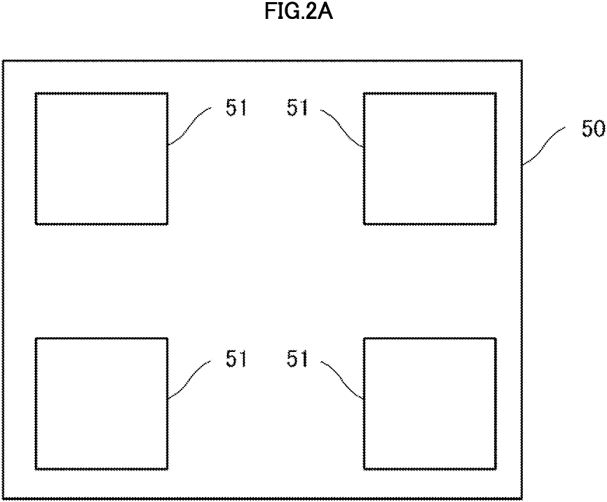

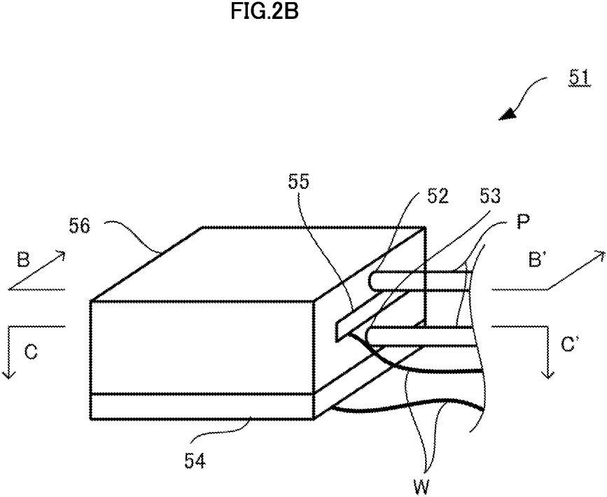

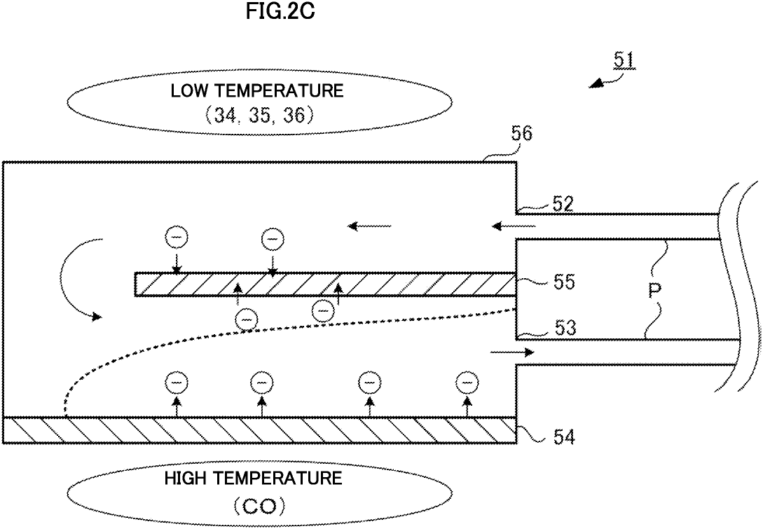

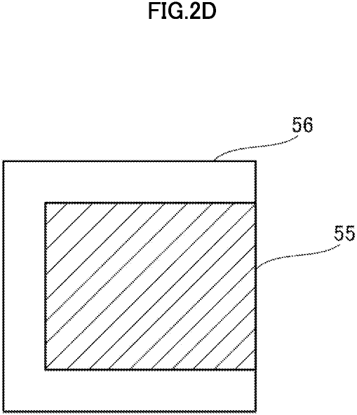

As illustrated in FIG. 2A, each of the electricity generation panels 50 includes four electricity generation cells 51 described later. Each of the electricity generation panels 50 is flat.

### Details of Electricity Generation Cell 51

Such an electricity generation cell 51 is an apparatus that takes out electrical energy from a difference between the temperatures of an object coming into contact with the electricity generation panel 50, to generate electricity.

As illustrated in FIG. 2B, the electricity generation cell 51 has a flat box shape. The electricity generation cell 51 includes a chamber 56 that stores electricity generation fluid described later. A cathode 54 and an anode 55 are connected to the electricity generation cell 51. A fluid inlet 52 which is an inlet of the electricity generation fluid and a fluid outlet 53 which is an outlet of the electricity generation fluid are formed in the chamber 56.

The four electricity generation cells 51 included in such an electricity generation panel 50 are connected to the storage battery 21 in parallel through the wiring lines W. Moreover, the four electricity generation cells 51 included in such an electricity generation panel 50 is connected to the pump 22 in parallel through the pipes P.

The cathode 54 is a metal plate and covers the lower part of the plastic chamber 56.

As illustrated in FIGS. 2C and 2D, the anode 55 projects into the interior of the chamber 56, and is fixed to a position that is not electrically connected to the cathode 54. The anode 55 is a metal plate.

With regard to the electricity generation panel 50 stored in the temperature holding chamber 31, the cold insulator 34 is located on the upper side of the electricity generation panel 50, and the object to be cooled CO is located below the electricity generation panel 50. Therefore, the temperature of the cathode 54 of each of the electricity generation cells 51 embedded in the electricity generation panel 50 is relatively higher than that of each anode 55 cooled by the cold insulator 34.

### Details of Electricity Generation Fluid

The electricity generation fluid is fluid in which electrons are exchanged between the cathode 54 and the anode 55 to generate electricity. The electricity generation fluid includes a redox couple and an ionic liquid described below. The redox couple is a compound that is oxidized or reduced at a temperature in the vicinity of a temperature at which the states of the cold insulators 34, 35, and 36 described later are changed.

The redox couple includes, for example, Co^{II}(bpy)₃(NTf₂)₂ and Co^{III}(bpy)₃(NTf₂)₃.

In such a case, bpy is 2,2'-bipyridine, and NTf₂ is bis(trifluoromethylsulfonyl)amide.

The ionic liquid is, for example, [C₂mim][NTf₂]. C₂mim is 1-ethyl-3-methylimidazolium.

The electricity generation fluid flows in the interior of each of the electricity generation cells 51 through a path illustrated in FIG. 2C.

First, the electricity generation fluid flows in from the fluid inlet 52, and flows from the right to the left facing the drawing in the upper portion of the chamber 56. As described above, each electricity generation panel 50 comes into contact with the object to be cooled CO and the cold insulator 34, 35, or 36, and the electricity generation cells 51 are embedded in each electricity generation panel 50. Therefore, the cold insulator 34, 35, or 36 is located on each chamber 56, and the thermal energy of the electricity generation fluid is consumed to cool the electricity generation fluid when the electricity generation fluid flows through the upper portion of the chamber 56.

When arriving at the inner wall of each chamber 56, the electricity generation fluid passes through a gap between the anode 55 and the chamber 56, and arrives at the lower side of the cathode 54 in the chamber 56.

Subsequently, the electricity generation fluid flows from the left to the right facing the drawing between the cathode 54 and the anode 55. At this time, the electricity generation fluid receives the thermal energy of the object to be cooled CO, thereby resulting in an increase in the temperature of the electricity generation fluid, because the object to be cooled CO, which is not illustrated, is present below the chamber 56.

The electricity generation fluid has properties of being reduced at high temperature and oxidized at low temperature. Therefore, the proportion of reduced electricity generation fluid is higher than the proportion of oxidized electricity generation fluid in a portion closer to the cathode 54, and the proportion of reduced electricity generation fluid is higher than the proportion of oxidized electricity generation fluid in a portion closer to the anode 55. The dashed line indicates an example of a boundary between portions in which the proportions of oxidized electricity generation fluid and reduced electricity generation fluid are equal to each other. The oxidized electricity generation fluid is more than the reduced electricity generation fluid in the proportion above the dashed line, while the reduced electricity generation fluid is more than the oxidized electricity generation fluid in the portion, particularly close to the cathode 54, below the dashed line.

The electricity generation fluid receives electrons from the cathode 54 when being reduced, and donates electrons to the anode 55 when being oxidized. Therefore, a potential difference between the cathode 54 and the anode 55 occurs. The potential difference that occurs between the cathode 54 and the anode 55 in such a manner is stored in the storage battery 21 connected through the wiring lines W.

The number of electricity generation cells 51 included in one electricity generation panel 50 is not limited to four, and may be more or less than four.

The arrangement of the electricity generation cells 51 in each electricity generation panel 50 is not limited to the described arrangement.

Each electricity generation panel 50 is an example of a first indoor electricity generator, a second indoor electricity generator, and an intra-chamber electricity generator in claims.

### Details of Cold Insulators 34, 35, and 36

The cold insulators 34, 35, and 36 are cold insulators of which the states are changed from solid to liquid at temperatures that are not more than temperatures at which the objects to be cooled CO stored in the temperature holding chambers 31, 32, and 33 are preserved, and differ depending on the kinds, amounts, and the like of the objects to be cooled CO, for example, at -20° C., -10° C., and 0° C. The cold insulators 34, 35, and 36 have heat capacities in which temperatures of -20° C., -10° C. or less, and 0° C. or less are held while the objects to be cooled CO are preserved.

Specific examples of the cold insulators 34, 35, and 36 of which the states are changed in such a manner will now be described.

The cold insulators 34, 35, and 36 include, for example, water and a water absorptive polymer.

The cold insulators 34, 35, and 36 include water. Therefore, the heat capacities of the cold insulators 34, 35, and 36 are relatively large, and the temperatures of the cold insulators 34, 35, and 36 are relatively gently changed. At certain temperatures, the states of the cold insulators 34, 35, and 36 are changed from solid to liquid or from liquid to solid. The cold insulators 34, 35, and 36 include a water absorptive polymer at different rates, respectively, and therefore, the states of the cold insulators 34, 35, and 36 are changed at the different temperatures.

The water absorptive polymer is, for example, sodium polyacrylate. The rates of water and the water absorptive polymer are, for example, experimentally set according to the temperatures of the cold insulators 34, 35, and 36 of which the states are intended to be changed.

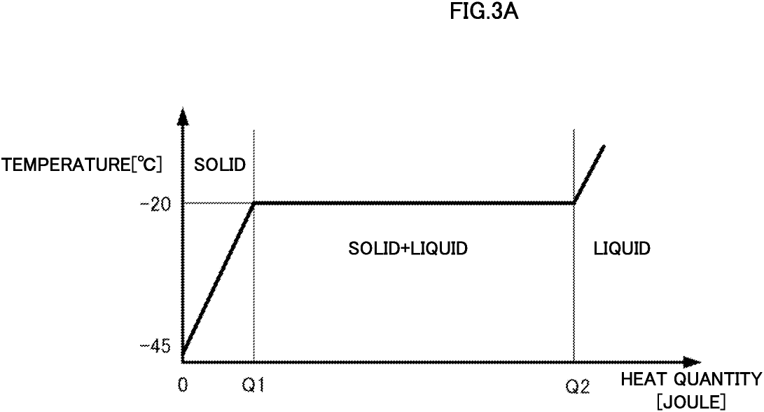

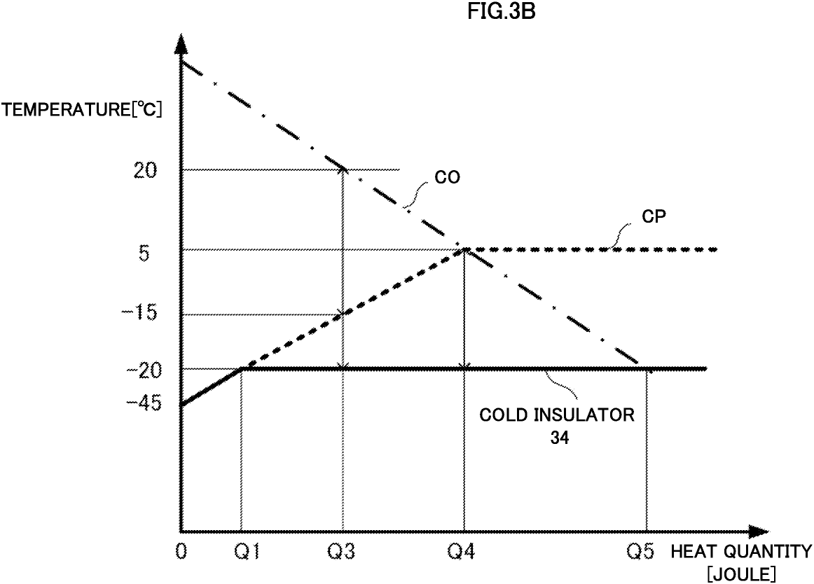

In a case in which the cold insulator 34 of which the state is changed at -20° C. is taken as an example, relationships between the quantity of applied heat, a temperature, and the state will be described below with reference to FIG. 3A.

The temperature of the cold insulator 34 is gradually increased, for example, by cooling the cold insulator 34 to an initial temperature of -45° C. and then applying heat to the cold insulator 34. However, when the temperature of the cold insulator 34 reaches -20° C., the temperature is not increased from -20° C. even by applying heat to the cold insulator 34, and a part of the cold insulator 34 begins to melt. It is assumed that the quantity of heat applied to the cold insulator 34 from -45° C. to -20° C. is Q1 J.

When the quantity of heat applied to the cold insulator 34 exceeds Q1 J, a part of the cold insulator 34 becomes liquid from solid. In a case in which heat is further applied to the cold insulator 34 in such a state, the temperature of the cold insulator 34 begins to increase to more than -20° C. when the quantity of the applied heat reaches Q2 J. At this time, the whole cold insulator 34 is in a liquid state. In the cold insulator 34, a temperature of -20° C. is held in a received heat quantity between Q1 J and Q2 J in calculation from an initial temperature of -45° C. in such a manner.

Like the cold insulator 34, constant temperatures, for example, -10° C. and 0° C. are also held during changes in the states of the cold insulators 35 and 36.

The substances included in the cold insulators 34, 35, and 36 and the heat characteristics of the cold insulators 34, 35, and 36 are described above as examples. The cold insulators 34, 35, and 36 may not optionally include the water absorptive polymer, and may include a substance other than water or such a water absorptive polymer, for example, an antiseptic agent, a coloring agent, or the like. The cold insulators 34, 35, and 36 may be cold insulators of which the states are changed at temperatures except the temperatures described above.

The cold insulators 34, 35, and 36 are examples of a first cold insulator and a second cold insulator in claims. Moreover, the temperatures at which the states of the cold insulators 34, 35, and 36 are changed are examples of a first temperature and a second temperature in claims.

Since the temperatures at which the states of the cold insulators 34, 35, and 36 are changed are different, each electricity generation panel 50 is optimized so that oxidation-reduction reaction vigorously occurs at a temperature in the vicinity of the temperature at which the state of each of the cold insulators 34, 35, and 36 is changed.

### Place Where Electricity Generation Panel 50 is Placed

Like the interior of the temperature holding chamber 31, the cold insulator 35 and the electricity generation panel 50 are placed in the interior of the temperature holding chamber 32. Like the interiors of the temperature holding chambers 31 and 32, the cold insulator 36 and the electricity generation panel 50 are also placed in the interior of the temperature holding chamber 33. The electricity generation panels 50 are also placed between the temperature holding chamber 31 and the temperature holding chamber 32, and between the temperature holding chamber 32 and the temperature holding chamber 33, respectively.

Each electricity generation panel 50 generates electricity on the basis of a difference between the temperatures of the cold insulator 34, 35, or 36, and the object to be cooled CO, in each of the interiors of the temperature holding chambers 31, 32, and 33. Moreover, each electricity generation panel 50 generates electricity on the basis of a temperature difference between the temperature holding chamber 31 and the temperature holding chamber 32, or between the temperature holding chamber 32 and the temperature holding chamber 33, between the temperature holding chamber 31 and the temperature holding chamber 32, or between the temperature holding chamber 32 and the temperature holding chamber 33.

The controller 20 includes a charging circuit and a backflow prevention circuit which are not illustrated, and electrical energy generated by the electricity generation cells 51 are stored in the storage battery 21. Part of the energy stored in the storage battery 21 is supplied to the pump 22 through the wiring lines W, and is used as energy with which the pump 22 is operated.

The remainder, which is not used as the energy with which the pump 22 is operated, of the energy of electricity that is generated by the electricity generation cells 51 and stored in the storage battery 21 can be consumed by an instrument other than the pump 22, for example, an external instrument connected through the electric connector 23.

The controller 20 may include a branch circuit that detects the voltage or current of each wiring line W, preferentially supplies energy in an amount required for operating the pump 22, of the energy stored in the storage battery 21, to the pump 22, and distributes the remainder to the electric connector 23.

Unlike the cool container described in Patent Literature 1, the cool box 1 includes, in the interiors of the temperature holding chambers 31, 32, and 33, the electricity generation panels 50 that generate electricity on the basis of the temperature differences between the objects to be cooled CO and the cold insulators 34, 35, and 36, or of the temperature differences between the temperature holding chambers 31, 32, and 33, as described above. Therefore, the cool box 1 can take energy, which can be utilized, out of thermal energy transferring from the objects to be cooled CO to the cold insulators 34, 35, and 36, or thermal energy transferring between the temperature holding chambers 31, 32, and 33.

Accordingly, the cool box 1 can utilize, as an energy source, thermal energy which has not been conventionally utilized, and therefore, the cool box 1 can efficiently utilize energy in comparison with conventional ones.

Moreover, the cool box 1 includes the temperature holding chambers 31, 32, and 33 that hold different temperatures, and therefore, perishable foods having different optimal storage temperatures can be preserved in one cool box 1.

### Comparison with Refrigerant CP with Changing Temperature

The cool box 1 generates electricity by utilizing the temperature ranges of the cold insulators 34, 35, and 36, in which the temperatures of the cold insulators 34, 35, and 36 are not changed even if the cold insulators 34, 35, and 36 receive thermal energy. Therefore, the cool box 1 achieves high electricity generation efficiency in comparison with a case in which electricity is generated with a refrigerant CP of which the temperature is changed depending on the quantity of received thermal energy. The refrigerant CP is a virtual substance which is stored in the section 31a of the temperature holding chamber 31. The state of the refrigerant CP is not changed although the refrigerant CP has the same specific heat and heat capacity as the specific heat and heat capacity of the cold insulator 34.

This will be described with reference to FIGS. 3A and 3B by taking the cold insulator 34 as an example.

As illustrated in FIG. 3A, the temperature of the cold insulator 34 is not changed as long as the quantity of heat received from an initial temperature of -45° C. is in a range of Q1 to Q2 J even if the cold insulator 34 receives heat.

The continuous and dashed lines in FIG. 3B indicate respective relationships between the temperature changes and quantities of received heat of the cold insulator 34 illustrated in FIG. 3A and a refrigerant CP according to Comparative Example. The alternate long and short dash line indicates a relationship between the temperature change and quantity of drawn heat of the object to be cooled CO so that the temperature change of the object to be cooled CO can be compared with the temperature changes of the cold insulator 34 and the refrigerant CP. Q1 is the value of a heat quantity similar to Q1 in FIG. 3A, and indicates the quantity of heat received by the cold insulator 34 before the change of the state of the cold insulator 34 is started from an initial temperature of -45° C.

To facilitate understanding, the amount of thermal energy taken out by the electricity generation panels 50, in thermal energy transferring from the object to be cooled CO to the cold insulator 34 or the refrigerant CP, is not taken into consideration.

It is assumed that the cold insulator 34 and the refrigerant CP has been cooled to -45° C. The cold insulator 34 and the refrigerant CP have an equal heat capacity between an initial temperature of -45° C. and the reception of heat of Q1 J, and therefore exhibit a similar temperature change. After the reception of the heat of Q1 J, the temperature of the refrigerant CP is increased to more than -20° C. although the temperature of the cold insulator 34 is not changed while the cold insulator 34 holds -20° C.

At the time of the reception of heat of Q3 J, the temperature of the refrigerant CP is increased to -15° C. although the temperature of the cold insulator 34 remains at -20° C. Therefore, a temperature difference between the refrigerant CP and the object to be cooled CO in the case of using the refrigerant CP is less, resulting in the smaller amount of generated electricity based on the temperature difference, than a temperature difference between the cold insulator 34 and the object to be cooled CO in the case of using the cold insulator 34.

When the contact of the cold insulator 34 or the refrigerant CP with the object to be cooled CO is continued to transfer heat of Q4 J from the object to be cooled CO to the cold insulator 34 or the refrigerant CP, the temperature of the refrigerant CP is increased to 5° C. although the cold insulator 34 has an unchanged temperature of -20° C. The temperature of the object to be cooled CO is decreased to 5° C., and therefore, the temperatures of the refrigerant CP and the object to be cooled CO are equal to each other.

Therefore, in the case of using the refrigerant CP, the transfer of the heat of Q4 J results in no temperature difference, and therefore makes it impossible to generate electricity on the basis of the temperature difference. In contrast, in the case of using the cold insulator 34, a temperature difference of 25° C. remains, and therefore, the generation of electricity based on the temperature difference can be continued until the cold insulator 34 further receives heat of Q5 J to have a temperature equal to the temperature of the object to be cooled CO.

As described above, the cold insulator 34 enables greater electricity to be generated as long as the temperature difference continues to be maintained, and therefore has high electricity generation efficiency in comparison with the case of using the refrigerant CP of which the temperature is changed.

The electricity generation efficiency of the cool box 1 has been described above.

### Operation of Cool Box 1

The pump 22 circulates the electricity generation fluid using the energy stored in the storage battery 21. When flowing through the chambers 56, the electricity generation fluid results in oxidation-reduction reaction in the electricity generation cells 51, and therefore causes potential differences between the cathodes 54 and the anodes 55. Electrical energy generated by the electricity generation panels 50 including the electricity generation cells 51 is accumulated in the storage battery 21. At least part of the accumulated energy is supplied to the pump 22, and used as energy with which the electricity generation fluid is circulated.

Since the cold insulators 34, 35, and 36 have maintained melting points while the objects to be cooled CO are preserved, the constant temperatures of the temperature holding chambers 31, 32, and 33 are held while the objects to be cooled CO are preserved. Each of the temperature difference between the temperature holding chambers 31 and 32, and the temperature difference between the temperature holding chambers 32 and 33 is held at a constant value under such conditions. Therefore, the constant amount of generated electricity is maintained in each of the electricity generation panel 50 placed between the temperature holding chambers 31 and 32, and the electricity generation panel 50 placed between the temperature holding chambers 32 and 33. Accordingly, the cool box 1 continues to generate electrical energy with which the pump 22 is operated, while the objects to be cooled CO are cooled in the temperature holding chambers 31, 32, and 33.

The generation of electricity by the electricity generation cells 51, the accumulation of the generated electrical energy in the storage battery 21, and the supply of the accumulated energy to the pump 22 are repeated in such a manner.

In accordance with the cool box 1, electrical energy is taken out on the basis of not only the temperature differences between the interiors of the temperature holding chambers 31, 32, and 33 but also the temperature differences between the temperature holding chambers 31, 32, and 33, and therefore, the energy can be efficiently used.

### Quantitative Relationship of Energy

A relationship between energy supplied to the cool box 1 and energy obtained from the cool box 1 will be described below.

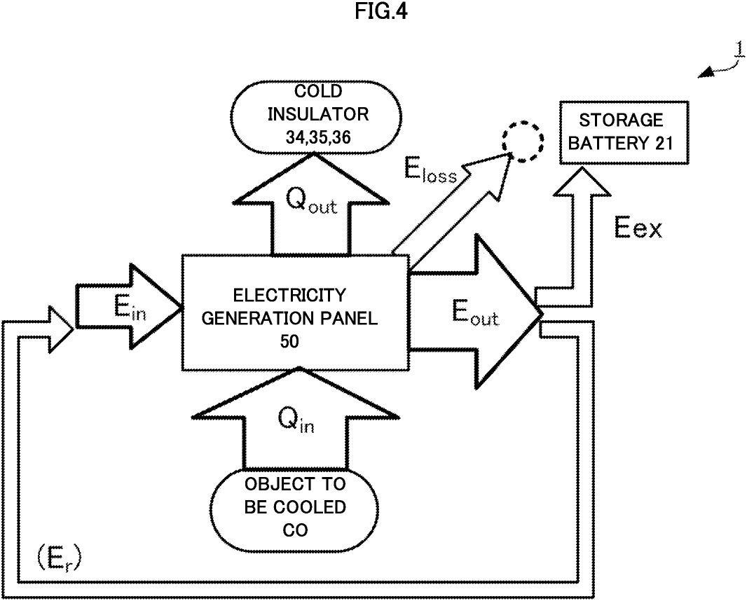

As illustrated in FIG. 4, heat flowing from each object to be cooled CO to each electricity generation panel 50 is set at Qin, and heat flowing from each electricity generation panel 50 to each of the cold insulators 34, 35, and 36 is set at Qout. Each electricity generation panel 50 generates electricity on the basis of a temperature difference. In other words, each electricity generation panel 50 has the function of converting a part of the difference between the received heat Qin and the released heat Qout into electrical energy Eout.

An energy loss due to friction, vibrations, and/or the like in each electricity generation panel 50 is set at Eloss. Energy with which the pump 22 that circulates the electricity generation fluid is operated is set at Ein.

In such a case, energy supplied to each electricity generation panel 50 and energy output from each electricity generation panel 50 are balanced with each other, and therefore, Ein + Qin = Eout + Qout + Eloss is established.

Moreover, the ratio of energy generated by each electricity generation panel 50 to energy required for operating each electricity generation panel 50 is expressed as Eout/Ein = 1 + (Qin— - Qout - Eloss)/Ein.

Since Ein is a positive value, the value of Eout/Ein is more than 1 when Eex = (Qin—- Qout - Eloss) is a positive value. In other words, the gain of the energy of the cool box 1 is more than 1 when Eex is a positive value. Eex is, for example, surplus energy stored in the storage battery 21.

In accordance with the cool box 1, the gain which is the ratio between the amount of supplied energy and the amount of obtained energy can be set at a value of more than 1, as described above. In accordance with the cool box 1, energy can be efficiently used because part of heat transferring to the cold insulators 34, 35, and 36 when the objects to be cooled CO are cooled can be taken as the energy, as described above.

### Embodiment 2

In the cool box 1, energy with which the pump 22 circulates the electricity generation fluid to the electricity generation panels 50 is provided from energy generated by the electricity generation panels 50.

For further stabilizing the generation of electricity, it is also acceptable to generate electrical energy by a power generator other than the electricity generation panels 50, and to supply the generated electrical energy to the pump 22.

A refrigerator vehicle 2 according to Embodiment 2 compensates energy, required for operation of the electricity generation panels 50, by photovoltaic power generation. Portions different from those of the cool box 1 will be described below.

### General Description of Refrigerator Vehicle 2

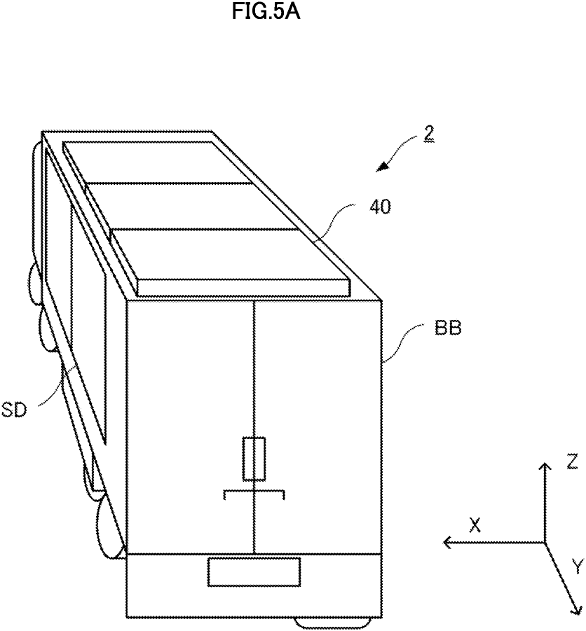

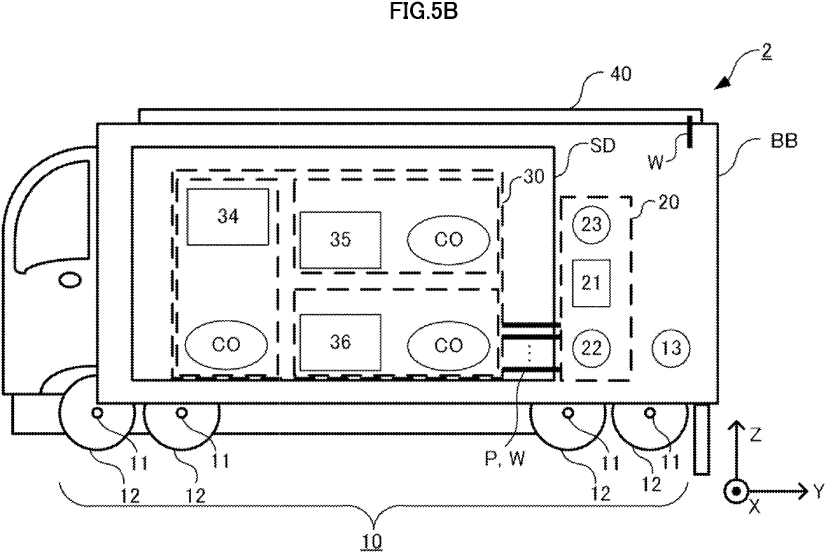

As illustrated in FIG. 5A, the refrigerator vehicle 2 is a van-body-type goods vehicle including a rear deck BB in the rear of the vehicle, and includes, on the ceiling of the rear deck BB, a photovoltaic power generator 40 that generates electricity by photovoltaic power generation to generate electrical energy.

The photovoltaic power generator 40 is a solar panel. The photovoltaic power generator 40 may include a fuse, and electric electronic circuits such as an inverter circuit and a stabilization circuit, as well as the solar panel.

The solar panel is an example of a solar battery in claims.

As illustrated in FIG. 5B, the refrigerator vehicle 2 includes a drive mechanism 10 that allows a vehicle body to travel.

The drive mechanism 10 includes shafts 11, tires 12 connected to the shafts 11, and a motor 13 connected to the shafts 11. The motor 13 is connected to the storage battery 21 through a wiring line W.

In addition, the drive mechanism 10 may further include a gear, a brake, an engine, an electric circuit, an electronic circuit, and/or the like, which are not illustrated.

In the refrigerator vehicle 2, the cool container 30 described above is mounted in the rear deck BB.

The cool container 30 can be accessed in the state of opening a sliding door SD that is disposed on the side surface of the vehicle body and is opened by moving the sliding door SD from side to side.

### Operation of Refrigerator Vehicle 2

The photovoltaic power generator 40 and the controller 20 are connected to each other through a wiring line W, the energy of electricity generated by the photovoltaic power generator 40 is accumulated in the storage battery 21 through the controller 20.

The amount of electricity generated by the electricity generation panels 50 is decreased as the temperatures of the objects to be cooled CO stored in the temperature holding chambers 31, 32, and 33 approach the temperatures of the cold insulators 34, 35, and 36, respectively. Even if the amount of generated electricity is decreased, electrical energy supplied to the pump 22 is compensated with electrical energy generated by the photovoltaic power generator 40 while the refrigerator vehicle 2 travels. In accordance with the refrigerator vehicle 2, the storage of electricity in the storage battery 21 can be continued even if the amount of electricity generated by the electricity generation panels 50 is decreased, as described above.

### Balance of Energy

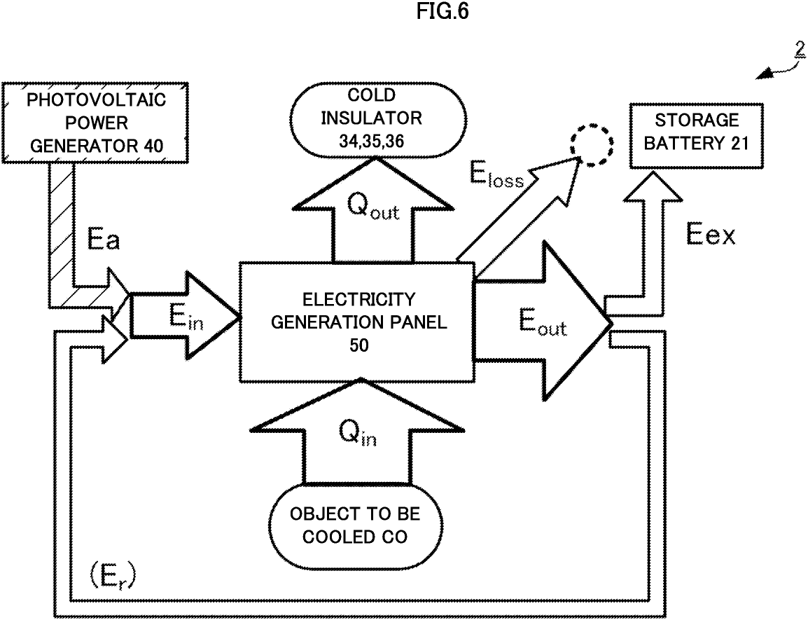

With regard to the balance of the energy of the refrigerator vehicle 2, points different from those of the cool box 1 will be described with reference to FIG. 6.

Energy generated by the photovoltaic power generator 40 is set at Ea.

The energy Ein supplied to the container is the total of Er, reused for generating electricity, of the energy of electricity generated by the refrigerator vehicle 2, and the energy Ea generated by the photovoltaic power generator, and therefore, a relationship of Ein = Er + Ea is satisfied.

Part of the energy Ein with which the electricity generation panels 50 are operated is compensated with Ea in such a manner. Therefore, the generation of electricity by the refrigerator vehicle 2 can be continued when the value of Ein is not less than a value required for generating electricity, for example, even if the value of electrical energy generated by the electricity generation panel 50 is decreased, and the energy Er which is fed back is zero.

In addition, the refrigerator vehicle 2 uses, as an energy source, not only photovoltaic power generation but also kinetic energy during traveling.

The motor 13 has a function as a power generator. Therefore, when the refrigerator vehicle 2 is decelerated, the shaft of the motor 13 is rotated to operate the motor 13 as a power generator and to convert the kinetic energy of the refrigerator vehicle 2 into electrical energy, whereby the electrical energy, into which the conversion has been performed, is supplied to the pump 22.

Accordingly, the refrigerator vehicle 2 enables continuation of stable generation of electricity even under an environment in which it is impossible to obtain sunlight.

In addition, in accordance with the refrigerator vehicle 2, the motor 13 is connected to the storage battery 21, and therefore, it is possible to convert energy, stored in the storage battery 21, into kinetic energy by the motor 13, and to allow the vehicle body to travel.

### Alternative Example

In the cool box 1 and the refrigerator vehicle 2, the electricity generation fluid is circulated to generate electricity. A power device is not limited to a device in which electricity generation fluid is used, and may be a solid-state device.

An electricity generation cell 351 according to Alternative Example generates electricity with a solid-state device.

Portions different from the electricity generation cells 51 of the cool box 1 and the refrigerator vehicle 2 will be described below.

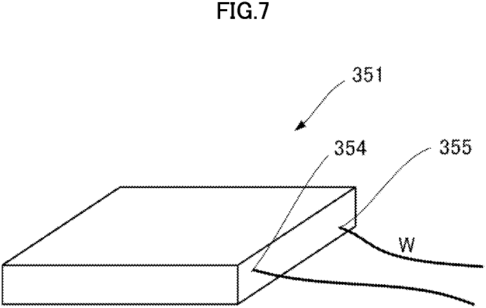

The electricity generation cell 351 is a Peltier device which is a solid-state device. As shown in FIG. 7, the electricity generation cell 351 includes a cathode 354 and an anode 355. The Peltier device is a device that generates electrical energy on the basis of a difference between the temperatures of both surfaces of the device having a plate shape, and the electrical energy is taken out through the cathode 354 and the anode 355.

Unlike the electricity generation cells 51, it is not necessary to circulate electricity generation fluid in the electricity generation cell 351. Therefore, a pipe P is not connected to the electricity generation cell 351.

Because the pipe P is not connected, the electricity generation cell 351 can be allowed to be smaller than each electricity generation cell 51, and the whole size of an electricity generation panel 50 including the electricity generation cell 351 or a cool container 30 including the electricity generation panel 50 can be reduced.

Moreover, the electricity generation cell 351 does not require electric power from outside the electricity generation cell 351 when being operated. Therefore, in accordance with the electricity generation panel 50 including the electricity generation cell 351, generation of electricity can be continued for relatively longer time even if the amount of the generated electricity is small.

In the present disclosure, energy which has not been conventionally utilized is utilized, as described above.

Therefore, in view of the possibility of leading to a reduction in demand for electricity obtained by thermal power generation resulting in emission of carbon dioxide, the present disclosure is environmentally friendly, and contributes to the achievement of the goal of sustainable development.

Moreover, the present disclosure also has the effect of developing clean energy in view of the possibility of generating electricity even under an environment in which it is impossible to obtain electric power.

The heat capacity of the cold insulator 34, 35, or 36 is not limited to the above as long as it is possible to generate electricity by the electricity generation cell 51 or 351.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Pat. Application No. 2020-081358, filed on May 1, 2020, the entire disclosure of which is incorporated by reference herein.

### REFERENCE SIGNS LIST

1 Cool box
2 Refrigerator vehicle
10 Drive mechanism
11 Shaft
12 Tire
13 Motor
20 Controller
21 Storage battery
22 Pump
23 Electric connector
30 Cool container
31, 32, 33 Temperature holding chamber
31a, 31b Section
31g, 32g Heat transfer portion
31w, 32w, 33w Thermally insulated wall
32a, 32b Section
33a, 33b Section
34, 35, 36 Cold insulator
40 Photovoltaic power generator
50 Electricity generation panel
51 Electricity generation cell
52 Fluid inlet
53 Fluid outlet
54 Cathode
55 Anode
56 Chamber
351 Electricity generation cell
354 Cathode
355 Anode
BB Rear deck
CO Object to be cooled
D1, D2, D3 Door
W Wiring line
P Pipe

1. A container comprising:
a first temperature holding chamber that stores a first object to be cooled, a first cold insulator of which a state is changed at a first temperature, and a first indoor electricity generator that generates electricity based on a difference between temperatures of the first object to be cooled and the first cold insulator comprising the first temperature, and holds the temperature of the first object to be cooled;
a second temperature holding chamber that stores a second object to be cooled, a second cold insulator of which a state is changed at a second temperature, and a second indoor electricity generator that generates electricity based on a difference between temperatures of the second object to be cooled and the second cold insulator comprising the second temperature, and holds the temperature of the second object to be cooled; and
an intra-chamber electricity generator that is placed between the first temperature holding chamber and the second temperature holding chamber, thermally connects the first temperature holding chamber and the second temperature holding chamber to each other, and generates electricity based on a difference between temperatures of the first temperature holding chamber and the second temperature holding chamber.

2. The container according to claim 1, wherein
each of the first temperature holding chamber and the second temperature holding chamber is surrounded by a thermally insulated wall, and
a portion of the thermally insulated wall that comes into contact with the intra-chamber electricity generator is thinner than a portion of thermally insulated wall that does not come into contact with the intra-chamber electricity generator.

3. An automobile comprising:
the container according to claim 1;
a solar battery that supplies generated energy to the first indoor electricity generator, the second indoor electricity generator, or the intra-chamber electricity generator; and
a drive mechanism that allows a vehicle body to travel using electrical energy generated by the first indoor electricity generator, the second indoor electricity generator, or the intra-chamber electricity generator.

4. An automobile comprising:
the container according to claim 2;
a solar battery that supplies generated energy to the first indoor electricity generator, the second indoor electricity generator, or the intra-chamber electricity generator; and
a drive mechanism that allows a vehicle body to travel using electrical energy generated by the first indoor electricity generator, the second indoor electricity generator, or the intra-chamber electricity generator.
